(19) United States
(12) Patent Application Publication
(10) Pub. No.: US 2024/0213068 A1
(43) Pub. Date: Jun. 27, 2024

(54) CASSETTE TRANSPORT DEVICE AND CASSETTE TRANSPORT SYSTEM INCLUDING THE SAME

(71) Applicant: Samsung Display Co., LTD., Yongin-si (KR)

(72) Inventors: Min Chul JUNG, Yongin-si (KR); Heung Won LEE, Yongin-si (KR); Hyun Sik CHOI, Yongin-si (KR)

(21) Appl. No.: 18/480,099

(22) Filed: Oct. 3, 2023

(30) Foreign Application Priority Data
Dec. 23, 2022 (KR) 10-2022-0182551

(51) Int. Cl. H01L 21/677

(52) U.S. Cl. CPC H01L 21/67706; H01L 21/6773; H01L 21/67733

(57) ABSTRACT

A cassette transport device and a cassette transport system including the same are provided. A cassette transport device includes a main body, a travel unit to move the main body, and a plurality of flow-rate maintaining members to generate a flow of air in a direction opposite to a traveling direction of the main body, and flow-rate maintaining members of the plurality of flow-rate maintaining members are stacked on one another on the main body, arranged on a rearward side with respect to the traveling direction of the main body, and include a plurality of fans.

### CROSS-REFERENCE TO RELATED APPLICATION

This application claims priority to and the benefit of Korean Patent Application No. 10-2022-0182551, filed on Dec. 23, 2022 in the Korean Intellectual Property Office, the entire disclosure of which is incorporated herein by reference.

### BACKGROUND

### 1. Field

Aspects of embodiments of the present disclosure relate to a cassette transport device and a cassette transport system including the same.

### 2. Description of the Related Art

As the information-oriented society evolves, various demands for display devices are increasing. For example, display devices are being employed by a variety of electronic devices such as smartphones, digital cameras, laptop computers, navigation devices, and smart televisions. Display devices may be flat-panel display devices, such as any of a liquid-crystal display device, a field emission display device, and an organic light-emitting display device, for example.

The processes of fabricating a display device include a number of processes, such as a process of fabricating a substrate, a process of fabricating a cell, and a module process. Such processes of fabricating a display device including a number of unit processes are typically conducted in a clean room. Once a number of substrates have been completed by certain process equipment inside the clean room, they may be loaded onto a cassette and then transported to other process equipment in the clean room by an automatic guided vehicle (AGV).

A plurality of stockers may be disposed inside the clean room to temporarily store substrates loaded in the cassette if a process is already being processed in other process equipment. Typically, an overhead shuttle (OHS) may be used for transporting a cassette from one stocker to another stocker in order to allow equipment and lines to be disposed thereunder.

A cassette transport device using an overhead shuttle may be guided by a travel rail installed along the ceiling of a clean room. Due to ambient airflow generated while the cassette transport device is moving, particles or foreign substances on the travel rail may penetrate into the cassette. In particular, when the cassette transport device decelerates or stops, contamination may be severe near the rear side of the cassette due to a vortex generated behind the cassette transport device.

### SUMMARY

According to aspects of embodiments of the present disclosure, a cassette transport device capable of reducing contamination of objects to be moved, and a cassette transport system including the same, are provided.

According to further aspects of embodiments of the present disclosure, a cassette transport device capable of maintaining a flow rate inside objects to be moved, and a cassette transport system including the same, are provided.

However, aspects and objects of the present disclosure are not limited to the above-mentioned aspects and objects, and other aspects and objects of the present disclosure will be apparent to those skilled in the art from the following descriptions.

According to one or more embodiments of the present disclosure, a cassette transport device includes a main body, a travel unit to move the main body, and a plurality of flow-rate maintaining members to generate a flow of air in a direction opposite to a traveling direction of the main body, and flow-rate maintaining members of the plurality of flow-rate maintaining members are stacked on one another on the main body, arranged on a rearward side with respect to the traveling direction of the main body, and include a plurality of fans.

The cassette transport device may further include a speed sensing unit configured to measure a speed of the main body, a plurality of air-pressure sensing units disposed in front of the flow-rate maintaining members, respectively, and a control processing device configured to control the plurality of flow-rate maintaining members, wherein the control processing device is configured to generate a signal for controlling a strength of the flow-rate maintaining members based on information provided from the speed sensing unit and the air-pressure sensing units, and wherein the air-pressure sensing units are disposed between the flow-rate maintaining members and an object to be moved, and are configured to measure air pressure and/or air flow rate in front of the plurality of flow-rate maintaining members.

The control processing device may further include a speed calculator and an air-pressure calculator configured to calculate required strengths of the flow-rate maintaining members based on the information provided from the speed sensing unit and the air-pressure sensing units, respectively, and a plurality of flow-rate control processors configured to generate signals for controlling the strengths of the flow-rate maintaining members based on calculation information of the speed calculator and the air-pressure calculator.

The flow-rate maintaining members may be respectively arranged at a side of a plurality of layers of an object to be moved.

The cassette transport device may further include a plurality of flow-rate reducing members respectively arranged at a rear side of the flow-rate maintaining members, wherein each of the flow-rate reducing members may include a front opening and a rear opening, and wherein the front opening may be smaller than the rear opening.

The flow-rate reducing members may have a shape that gradually widens from a front side to a rear side.

The cassette transport device may further include a direction changing member arranged on a rear side of the flow-rate maintaining members, wherein the direction changing member may include an opening facing a lower side, and may be arranged to cover a part of a rear surface of the main body.

The travel unit may include a main travel unit and an auxiliary travel unit arranged at a side of the main travel unit, wherein the auxiliary travel unit may include a vertical driver, and wherein a lowest end of the auxiliary travel unit may be configured to be selectively located at a lower level than a lowest end of the main travel unit by driving the vertical driver.

The strength of the flow-rate maintaining members may be increased as the speed of the main body decreases.

According to one or more embodiments of the present disclosure, a cassette transport device includes a main body, a travel unit configured to move the main body, and a plurality of fans configured to generate a flow of air in a direction opposite to a traveling direction of the main body, wherein fans of the plurality of fans may be stacked on one another on the main body, and arranged at a rearward side with respect to the traveling direction of the main body.

The cassette transport device may further include a speed sensing unit configured to measure a speed of the main body, a plurality of air-pressure sensing units arranged in front of the plurality of fans, respectively, and a control processing device configured to control the plurality of fans, wherein the control processing device may generate a signal for controlling wind strengths of the fans based on information provided from the speed sensing unit and the air-pressure sensing units.

The plurality of air-pressure sensing units may measure air pressure and/or flow rate of air in front of the plurality of fans, respectively.

The plurality of air-pressure sensing units may be arranged between the plurality of fans, respectively, and an object to be moved.

The control processing device may include a speed calculator and an air-pressure calculator configured to respectively calculate required wind strength of the fans based on information provided from the speed sensing unit and the air-pressure sensing units.

The control processing device may further include a plurality of flow-rate controller processors configured to generate signals to control the wind strength of the fans, respectively, based on calculated information provided from the speed calculator and the air-pressure calculator.

According to one or more embodiments of the present disclosure a cassette transport system includes any of the above-described cassette transport devices, a travel tunnel configured to move the cassette transport device, and an air filter unit arranged on the travel tunnel, wherein an upper surface of the travel tunnel may include a plurality of first openings, and wherein the air filter unit may inject purified air into the travel tunnel through the first openings.

The lower surface of the travel tunnel may include a plurality of second openings, and the air filter unit may generate an airflow from the first openings toward the second openings.

The cassette transport system may further include at least one stocker configured to store a cassette, and a buffer unit located between the stocker and the cassette transport device to temporarily store and relay the cassette.

The stocker may include a lifting device configured to lift the cassette, and at least one loading chamber configured to store the cassette.

The travel tunnel may connect an upper portion of the stocker with an upper portion of another stocker.

According to an aspect of one or more embodiments of the present disclosure, contamination of objects to be moved may be reduced.

According to another aspect of one or more embodiments of the present disclosure, flow rate inside objects to be moved may be maintained.

However, aspects and effects of the present disclosure are not limited to those described above and other aspects and effects of the present disclosure will be apparent to those skilled in the art from the following descriptions.

### BRIEF DESCRIPTION OF THE DRAWINGS

The above and other aspects and features of the present disclosure will become more apparent by describing in further detail some embodiments thereof with reference to the attached drawings.

FIG. 1 is a plan view of a cassette transport system according to an embodiment of the present disclosure.

FIG. 2 is a side view of the cassette transport system according to an embodiment of the present disclosure.

FIG. 3 is a perspective view showing a travel track and an air filter unit according to an embodiment.

FIG. 4 is a side view of a cassette transport device according to an embodiment of the present disclosure.

FIG. 5 is a plan view of the cassette transport device according to an embodiment.

FIG. 6 is a rear view of the cassette transfer device according to an embodiment.

FIG. 7 is a rear view of a travel unit according to an embodiment of the present disclosure.

FIG. 8 is a perspective view of a flow-rate reducing member according to an embodiment of the present disclosure.

FIG. 9 is a side view of the flow-rate reducing member according to an embodiment.

FIG. 10 is a block diagram of a control processing device according to an embodiment of the present disclosure.

FIG. 11 is a diagram conceptually illustrating a process of adjusting a flow rate by a control processing device and a flow-rate adjusting unit according to an embodiment of the present disclosure.

FIG. 12 is a side view showing a cassette transport device according to an embodiment when it is decelerating.

FIG. 13 is a graph showing flow rate according to a speed of the cassette transport device according to the embodiment.

FIGS. 14A and 14B show graphs comparing a degree of contamination of substrates transported by the cassette transport device according to an embodiment with the degree of contamination of substrates transported by a comparative cassette transport device.

FIG. 15 is a side view of a cassette transport device according to another embodiment of the present disclosure.

FIG. 16 is a side view showing the cassette transport device of FIG. 15 when it is decelerating.

### DETAILED DESCRIPTION

The present invention will now be described more fully herein with reference to the accompanying drawings, in which some embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It is also be understood that when a layer is referred to as being “on” another layer or substrate, it may be directly on the other layer or substrate, or one or more intervening layers may also be present. The same reference numbers indicate the same components throughout the specification.

It is to be understood that, although the terms “first,” “second,” etc. may be used herein to describe various elements, these elements should not be limited by these terms. These terms are used to distinguish one element from another element. For instance, a first element discussed below could be termed a second element without departing from the teachings of the present invention. Similarly, the second element could also be termed the first element.

Unless otherwise defined, all terms (including technical and scientific terms) used herein have the same meaning as commonly understood by one of ordinary skill in the art to which the inventive concept pertains. It is also to be understood that terms defined in commonly used dictionaries should be interpreted as having meanings consistent with the meanings in the context of the related art, and they are not interpreted in an ideal or overly formal sense, unless expressly defined herein.

Herein, some embodiments of the present disclosure will be described with reference to the accompanying drawings.

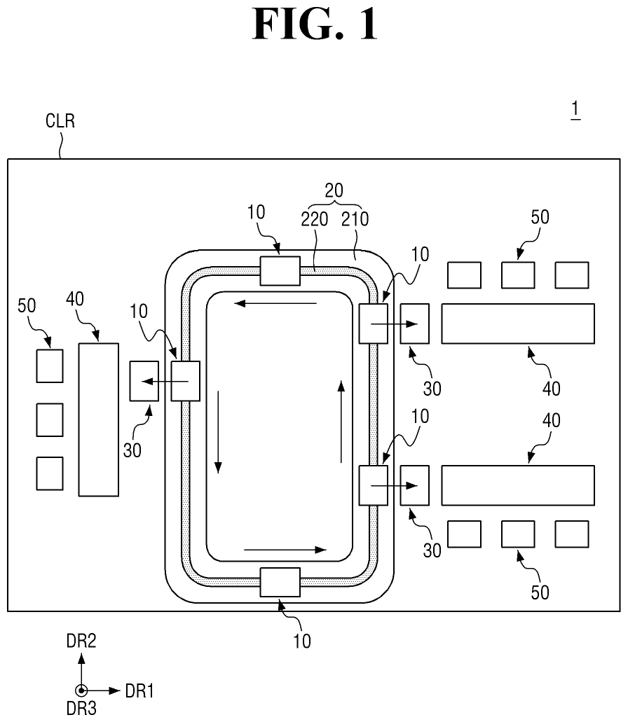

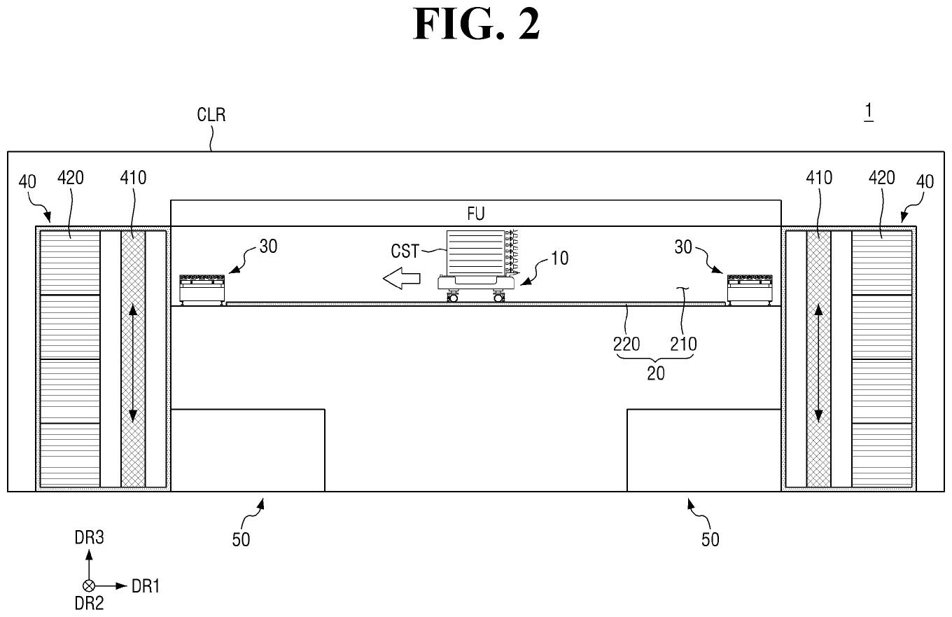

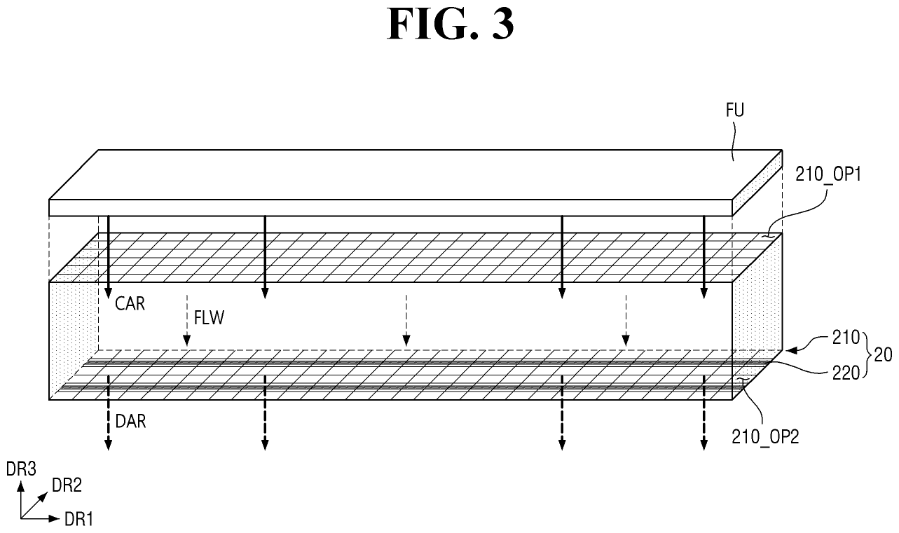

FIG. 1 is a plan view of a cassette transport system according to an embodiment of the present disclosure; FIG. 2 is a side view of the cassette transport system according to an embodiment of the present disclosure; and FIG. 3 is a perspective view showing a travel track and an air filter unit according to an embodiment.

Referring to FIGS. 1 to 3, a cassette transport system 1 according to an embodiment may be a transport system for transporting and storing a workpiece before and after processes of fabricating the workpiece. For example, the cassette transport system 1 may be a transport system for transporting and storing a substrate SUB in processes of fabricating a display device. It is to be understood, however, that the present disclosure is not limited thereto. For example, the cassette transport system may be broadly employed for a transport system in processes of fabricating a semiconductor or a variety of transport systems for other subjects. In the following description, an example will be described in which the cassette transport system 1 is used in processes of a display device, for convenience of illustration.

The cassette transport system 1 according to an embodiment may include a cassette transport device 10 for transporting a cassette CST loaded with substrates SUB; a travel track 20 along which the cassette transport device 10 moves; an air filter unit FU for supplying clean air CAR to the travel track 20; a buffer unit 30 for temporarily storing the cassette CST; a stocker 40 for storing the cassette CST; and a process equipment 50 for performing a process on the substrates SUB.

The cassette transport device 10 may transport an object to be moved. For example, the cassette transport device 10 may transport a cassette CST loaded with substrates SUB included in a display device as the object. The object to be moved may accommodate products used or fabricated in numerous unit processes during the processes of fabricating a display device. It is to be understood, however, that embodiments of the present disclosure are not limited thereto. A variety of members that accommodate products used and fabricated in processes of fabricating a semiconductor as well as display devices may be employed as the object to be moved according to an embodiment of the present disclosure. In the following description, an example will be described for convenience of illustration, in which the cassette CST loaded with substrates SUB is transported.

According to an embodiment, the cassette transport device 10 may be an automatic guided vehicle (AGV) used in an automated material handling system (AMHS). It is to be understood, however, that embodiments of the present disclosure are not limited thereto. A transport device that is manually moved by manpower may be employed as the cassette transport device 10, as well as various transport devices for transporting the cassette CST.

The cassette transport device 10 may be a kind of overhead shuttle (OHS). For example, the cassette transport device 10 may move along the travel track 20 installed on a ceiling or at a high location of a clean room CLR inside the clean room CLR.

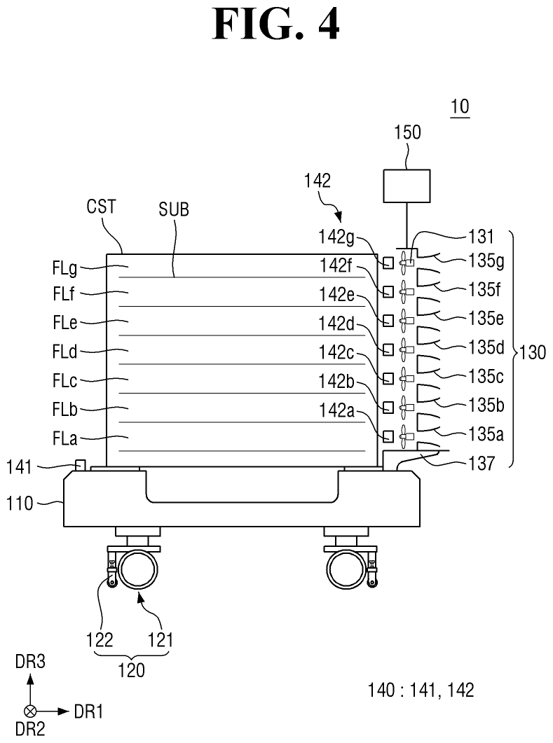

A configuration of the cassette transport device 10 will be described in further detail later with reference to FIG. 4 and the like.

The travel track 20 may be a passage or a rail along which the cassette transport device 10 moves. According to an embodiment in which the cassette transport device 10 is an overhead shuttle, the travel track 20 may be disposed at the ceiling or a high location of the clean room CLR inside the clean room CLR.

In some embodiments, the travel track 20 may include a travel tunnel 210 and a travel rail 220.

The travel tunnel 210 may be a passage that surrounds the cassette transport device 10 and the travel rail 220.

Referring to FIG. 3, the travel tunnel 210 may include a first open area 210_OP1 at a top and a second open area 210_OP2 at a bottom. Each of the first open area 210_OP1 and the second open area 210_OP2 may include one or more openings. In the first open area 210_OP1, clean air CAR supplied by the air filter unit FU may be introduced. In the second open area 210_OP2, dirty air DAR in the travel tunnel 210 may be discharged to an outside of the travel tunnel 210, i.e., to an inside of the clean room CLR.

According to an embodiment, each of the first open area 210_OP1 and the second open area 210_OP2 may have a mesh shape. It is to be understood, however, that embodiments of the present disclosure are not limited thereto. Each of the first open area 210_OP1 and the second open area 210_OP2 may have a shape in which openings and non-openings are arranged alternately or any shape via which air can move.

The travel rail 220 may be a rail road disposed along a path in which the cassette transport device 10 moves on a side of the cassette transport device 10. For example, as shown in the drawings, the travel rail 220 may be disposed under the cassette transport device 10, but embodiments of the present disclosure are not limited thereto. For example, the travel rail 220 may be disposed above or on a side of the cassette transport device 10.

The air filter unit FU may introduce clean air CAR into the travel tunnel 210. The air filter unit FU may be disposed above or on a side of the travel tunnel 210. According to an embodiment, a fan filter unit (FFU) or an equipment fan filter unit (EFU) may be used as the air filter unit FU.

In some embodiments, the air filter unit FU may generate an airflow FLW from the first open area 210_OP1 to the second open area 210_OP2 of the travel tunnel 210. For example, the clean air CAR purified through the air filter unit FU may be introduced into the travel tunnel 210 through the first open area 210_OP1, and the dirty air DAR may be discharged through the second open area 210_OP2 via an inside of the travel tunnel 210 by inertia and gravity. In an embodiment, the airflow FLW directed from the first open area 210_OP1 to the second open area 210_OP2 may be formed inside the travel tunnel 210. In this manner, it is possible to prevent or substantially prevent particles on a floor of the travel tunnel 210 from being scattered into the air inside the travel tunnel 210.

The buffer unit 30 may be disposed between the cassette transport device 10 and the stocker 40. The buffer unit 30 may temporarily store the cassette CST in order to prevent or substantially prevent a delay in a work process due to the transport of the cassette CST. Although the buffer unit 30 is disposed inside the travel tunnel 210 in the example shown in FIG. 2, embodiments of the present disclosure are not limited thereto.

In some embodiments, the buffer unit 30 may include a transport member (not shown) for transporting the cassette CST from the cassette transport device 10 onto the buffer unit 30. For example, the buffer unit 30 may include a transport roller (not shown) as the transport member. In an embodiment, when the cassette CST reaches where the buffer unit 30 is located by the cassette transport device 10, the cassette CST may be transported onto the buffer unit 30 by rotation of the transport roller. It is to be understood, however, that embodiments of the present disclosure are not limited thereto. For example, the transport member may be a transport member such as a conveyor belt and an arm.

The stocker 40 may be disposed at a side of the buffer unit 30. The stocker 40 may have a shape extended in a third direction DR3. The stocker 40 may include a lifting device 410 for lifting the cassette CST in the third direction DR3, and a loading chamber 420 storing the cassette CST.

In the drawings, a first direction DR1 and a second direction DR2 intersect each other as horizontal directions. For example, the first direction DR1 and the second direction DR2 may be perpendicular to each other. In addition, the third direction DR3 may intersect the first direction DR1 and the second direction DR2, and may be a vertical direction, for example. Herein, a side indicated by an arrow of each of the first to third directions DR1, DR2, and DR3 may be referred to as a first side, while an opposite side may be referred to as a side opposite side.

The lifting device 410 may have a shape extended along the third direction DR3. The lifting device 410 may transport the cassette CST in the third direction DR3. The lifting device 410 may include any of a variety of lifting devices, such as a rope-type elevator, a hydraulic elevator, and an elevation lift.

The loading chamber 420 may store the cassette CST. According to an embodiment of the present disclosure, the loading chamber 420 may include a plurality of chambers stacked on one another in the third direction DR3. The cassette CST stored on each floor of the loading chamber 420 may be lowered by the lifting device 410 and may be moved to the process equipment 50, and may be raised to another stocker 40 by the cassette transport device 10.

The process equipment 50 may perform a process on the substrates SUB. For example, the process equipment 50 may perform any of various fabricating processes on the substrates SUB, such as a cell fabricating process and a module process.

The process equipment 50 may be disposed at a side of the stocker 40. The process equipment 50 may be disposed at a bottom of the clean room CLR. For example, the process equipment 50 may be disposed at the bottom of the clean room CLR.

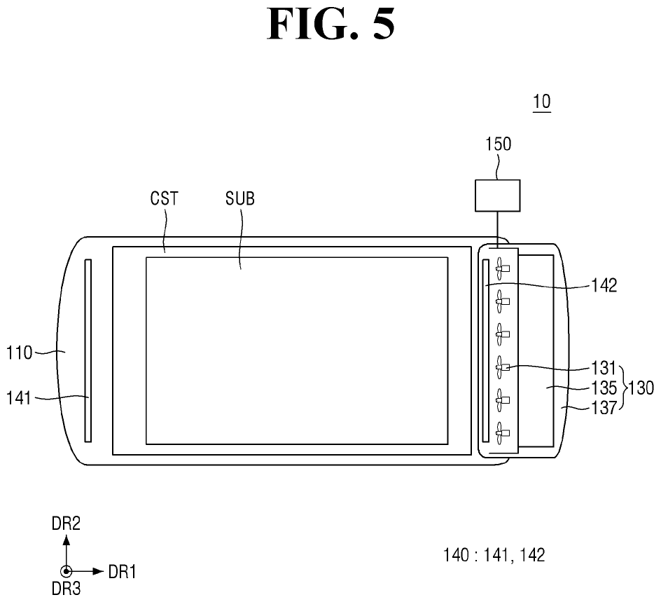

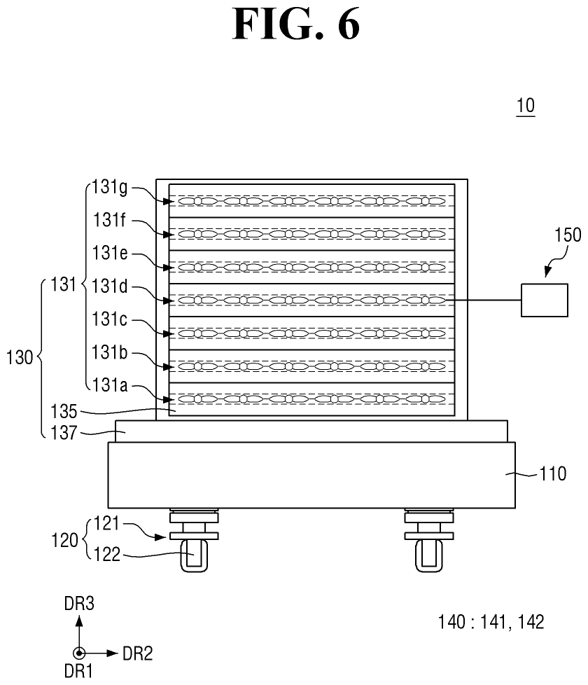

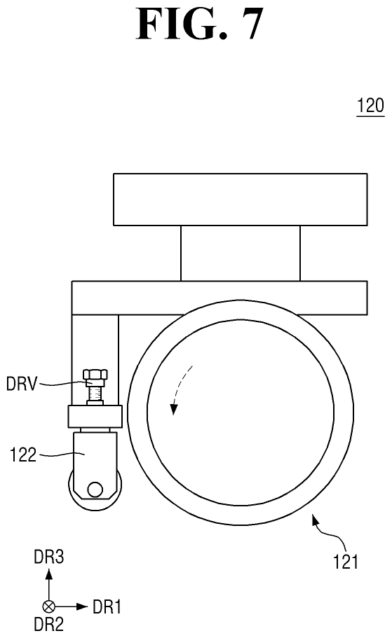

FIG. 4 is a side view of a cassette transport device according to an embodiment of the present disclosure; FIG. 5 is a plan view of the cassette transport device according to an embodiment; FIG. 6 is a rear view of the cassette transport device according to an embodiment; and FIG. 7 is a rear view of a travel unit according to an embodiment of the present disclosure.

Referring to FIGS. 4 to 7, the cassette transport device 10 may include a main body 110, a travel unit 120, a flow-rate adjusting unit 130, a sensing unit 140, and a control processing device 150.

The main body 110 may load the cassette CST thereon. The main body 110 may support the flow-rate adjusting unit 130, the sensing unit 140 and the control processing device 150 disposed thereon. The main body 110 may be disposed on the travel unit 120 disposed under the main body 110.

The main body 110 may move in the first direction DR1 and/or the second direction DR2 by driving the travel unit 120. The cassette CST may be transported with the movement of the main body 110.

The travel unit 120 may be disposed under the main body 110 to support the main body 110. The travel unit 120 may move the main body 110. For example, the travel unit 120 may be in the form of a wheel rotating along the travel rail 220. It is to be understood, however, that embodiments of the present disclosure are not limited thereto. In an embodiment, the travel unit 120 may move by magnetic levitation such that it is spaced apart from the travel rail 220 in the air.

In some embodiments, when the travel unit 120 is in the form of a wheel, the travel unit 120 may include a main travel unit 121 and an auxiliary travel unit 122.

The main travel unit 121 may be attached directly to and supported by the main body 110. The main travel unit 121 may be connected directly to the travel rail 220 in normal times and may move the main body 110 while rotating. According to an embodiment, there may be four main travel units 121 on front, rear, left, and right sides, but embodiments of the present disclosure are not limited thereto.

The auxiliary travel unit 122 may be disposed on a side of the main travel unit 121. The auxiliary travel unit 122 may move the main body 110 instead of the main travel unit 121 when the main travel unit 121 is damaged or out of order. According to an embodiment, a number of the auxiliary travel units 122 may be equal to a number of the main travel units 121, but embodiments of the present disclosure are not limited thereto.

In some embodiments, referring to FIG. 7, the auxiliary travel unit 122 may include a vertical driver DRV. A lower end of the auxiliary travel unit 122 may be selectively located lower than a lower end of the main travel unit 121 by driving of the vertical driver DRV. For example, the auxiliary travel unit 122 may descend toward the travel rail 220 and may be directly connected to the travel rail 220 by driving the vertical driver DRV. The auxiliary driving unit 122 may move the main body 110 while rotating.

The flow-rate adjusting unit 130 may be a device for maintaining a flow rate of air inside the cassette CST, which is the object to be moved. When the cassette transport device 10 moves along the travel track 20, a flow of air moving from a front of the cassette transport device 10 through an inside of the cassette CST to a rear of the cassette transport device 10 may occur. When the cassette transport device 10 accelerates, the flow rate of the air inside the cassette CST may increase, whereas, when the cassette transport device 10 decelerates, the flow rate of the air may decrease. The flow-rate adjusting unit 130 may maintain a constant flow rate of the air inside the cassette CST.

In an embodiment, the flow-rate adjusting unit 130 may include a plurality of flow-rate maintaining members 131, a plurality of flow-rate reducing members 135, and a support 137.

The plurality of flow-rate maintaining members 131 may be disposed on the support 137 disposed on the main body 110. A stack of the flow-rate maintaining members 131 may be disposed on the main body 110. For example, the flow-rate maintaining members 131 may include first to seventh flow-rate maintaining members 131a, 131b, 131c, 131d, 131e, 131f, and 131g stacked in the third direction DR3, as shown in FIG. 6. Although seven layers of the flow-rate maintaining members are shown in the drawings, the number of the flow-rate maintaining members 131 is not limited thereto.

The first to seventh flow-rate maintaining members 131a, 131b, 131c, 131d, 131e, 131f, and 131g may be arranged in the second direction DR2. Although each of the first to seventh flow-rate maintaining members 131a, 131b, 131c, 131d, 131e, 131f, and 131g is illustrated as including six elements in the drawings, the number of the elements of each of the first to seventh flow-rate maintaining members 131a, 131b, 131c, 131d , 131e, 131f, and 131g is not limited thereto.

The flow-rate maintaining member 131 may be disposed on a forward side with respect to the traveling direction of the main body 110. For example, the flow-rate maintaining members 131 may be disposed on a backward (or rearward) side of the cassette CST with respect to the traveling direction of the main body 110. Since the flow-rate maintaining member 131 is disposed behind the cassette CST, it is possible to prevent or substantially prevent particles from entering the inside of the cassette CST compared to when the members 131 are disposed in front of the cassette CST.

The flow-rate maintaining member 131 may generate a flow of air in a direction opposite to the traveling direction of the main body 110. For example, when the cassette transport device 10 moves in the opposite direction to the first direction DR1, the flow-rate maintaining members 131 may generate a flow of air in the first direction DR1.

In some embodiments, the flow-rate maintaining members 131 may include fans including blades. It is to be understood, however, that embodiments of the present disclosure are not limited thereto. The flow-rate maintaining members 131 may be a wind generating device without blades instead of a fan with blades. Any device may be employed as the flow-rate maintaining members 131 as long as it can generate air flow in the direction opposite to the traveling direction of the main body 110.

The plurality of flow-rate reducing members 135 may be disposed on the support 137 disposed on the main body 110. A stack of the flow-rate reducing members 135 may be disposed on the main body 110. For example, the flow-rate reducing members 135 may include first to seventh flow-rate reducing members 135a, 135b, 135c, 135d, 135e, 135f, and 135g stacked in the third direction DR3, as shown in FIG. 4. The first to seventh flow-rate maintaining members 135a, 135b, 135c, 135d, 135e, 135f, and 135g may be disposed at a side of the first to seventh flow-rate maintaining members 131a, 131b, 131c, 131d, 131e, 131f, and 131g, respectively.

According to an embodiment, a number of layers of the plurality of flow-rate reducing members 135 may be equal to a number of layers of the plurality of flow-rate maintaining members 131. Although seven layers of the flow-rate reducing members are shown in the drawings, the number of the layers of the flow-rate reducing members 135 is not limited thereto.

The flow-rate reducing members 135 may be disposed on the backward (or rearward) side of the flow-rate maintaining members 131, respectively, with respect to the traveling direction of the main body 110. The flow-rate reducing members 135 may reduce the flow rate of the air passing through the flow-rate maintaining members 131. As such, the flow-rate reducing members 135 are disposed behind the flow-rate maintaining members 131 to reduce the flow rate of air, such that it is possible to prevent or substantially prevent particles from penetrating another cassette transport device 10 that follows.

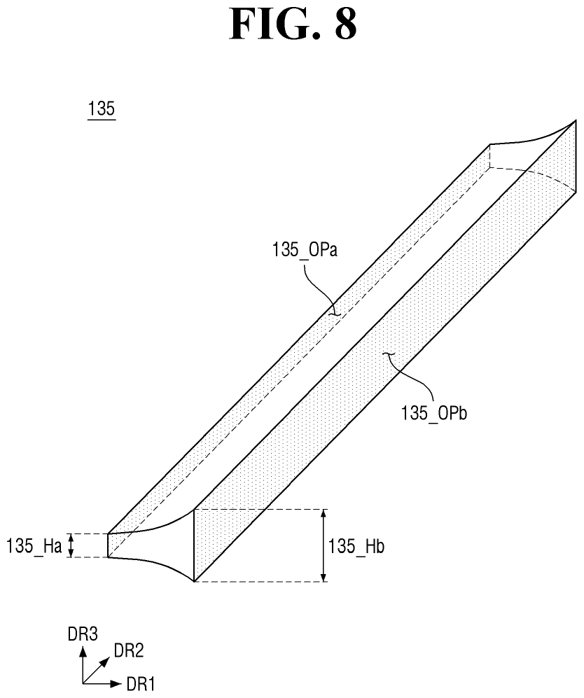

A configuration of the flow-rate reducing member 135 will be described in further detail later with reference to FIG. 8 and the like.

The support 137 may be disposed on the main body 110 and may be disposed on the backward (or rearward) side with respect to the traveling direction of the main body 110. The support 137 may support the flow-rate maintaining members 131 and the flow-rate reducing members 135.

In an embodiment, the sensing unit 140 may include a speed sensing unit 141 configured to measure a speed of the main body 110, and a plurality of air-pressure sensing units 142 configured to measure a flow rate of air and/or atmospheric pressure.

The speed sensing unit 141 may measure the speed of the main body 110. According to the embodiment, the speed sensing unit 141 may include any of a Hall effect speed sensor, a variable reluctance speed sensor (VRS), an optical speed sensor, an ultrasonic speed sensor, a radar type speed sensor, an electronic speed sensor, etc.

In some embodiments, the speed sensing unit 141 may be disposed at a forward side of the main body 110. It is to be understood, however, that embodiments of the present disclosure are not limited thereto. The speed sensing unit 141 may be disposed at any of a variety of positions as long as the speed sensing is not interfered.

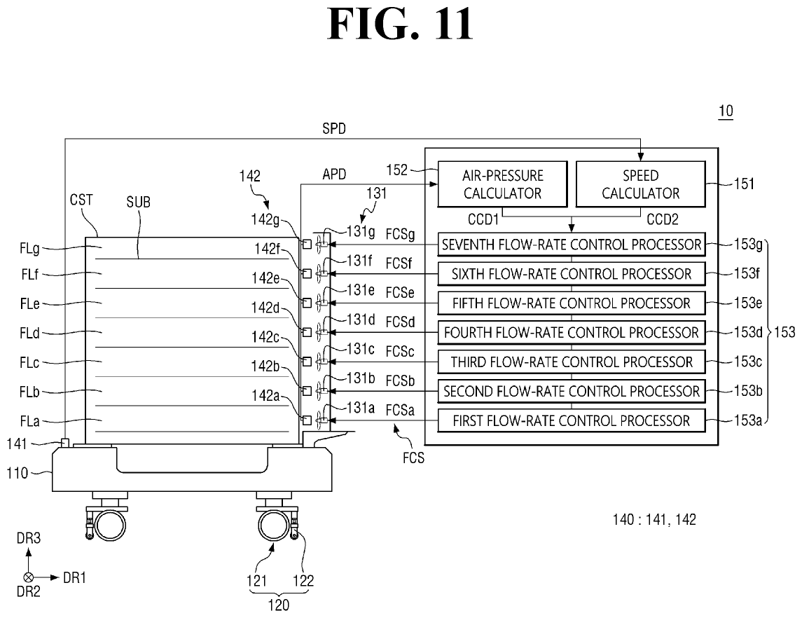

The speed sensing unit 141 may measure the speed of the main body 110 and may provide speed information SPD (see FIG. 11), which is information of the speed of the main body 110, to the control processing device 150.

The plurality of air-pressure sensing units 142 may measure flow rate of air and/or air pressure. According to an embodiment, the air-pressure sensing units 142 may include any of a Hall effect flow sensor for measuring a flow rate of air, a flow sensor for measuring air pressure, a windmill wind speed sensor, a wind speed sensor in a wind turbine, an ultrasonic wind speed sensor, etc. According to another embodiment, the air-pressure sensing units 142 may include a piezoresistive air-pressure sensor, such as a micro electromechanical systems (MEMS) air-pressure sensor for measuring air pressure, a digital air pressure sensor with resistance wire, etc.

In some embodiments, a stack of the air-pressure sensing units 142 may be disposed on the main body 110. For example, the air-pressure sensing units 142 may include first to seventh air-pressure sensing units 142a, 142b, 142c, 142d, 142e, 142f, and 142g stacked in the third direction DR3, as shown in FIG. 4. The first to seventh air-pressure sensing units 142a, 142b, 142c, 142d, 142e, 142f, and 142g may be disposed at a side of the first to seventh flow-rate maintaining members 131a, 131b, 131c, 131d, 131e, 131f, and 131g, respectively.

A number of layers of the air-pressure sensing units 142 may be equal to a number of layers of the plurality of flow-rate maintaining members 131. Although seven layers of the air-pressure sensing units 142 are shown in the drawings, the number of the layers of the air-pressure sensing units 142 is not limited thereto.

The air-pressure sensing units 142 may be disposed at a forward side of the flow-rate maintaining members 131, respectively, with respect to the traveling direction of the main body 110. The air-pressure sensing units 142 may measure air pressure and/or flow rate of air in front of the plurality of flow-rate maintaining members 131, respectively. For example, the first to seventh air-pressure sensing units 142a, 142b, 142c, 142d, 142e, 142f, and 142g may measure the air pressure and/or flow rate of air in front of the first to seventh flow-rate maintaining members 131a, 131b, 131c, 131d, 131e, 131f, and 131g, that is, behind first to seventh layers FLa, FLb, FLc, FLd, FLe, FLf, and FLg of the cassette CST.

The air-pressure sensing units 142 may measure air pressure and/or flow rate of air of each layer (e.g., FLa, FLb, FLc, FLd, FLe, FLf, and FLg) of the cassette CST to provide air pressure information APD (see FIG. 11), which is information of air pressure and/or flow rate of air of the main body 110 to the control processing device 150.

The control processing device 150 may control the strength of the flow-rate maintaining members 131. In an embodiment, the control processing unit 150 may include a speed calculator 151 that receives speed information SPD (see FIG. 11) from the speed sensing unit 141; an air-pressure calculator 152 that receives air-pressure information APD (see FIG. 11) from the air-pressure sensing units 142; and flow-rate control processors 153 configured to control the strength of the flow-rate maintaining members 131 based on calculated information CCD1 and CCD2 (see FIG. 11) of the speed calculator 151 and the air-pressure calculator 152.

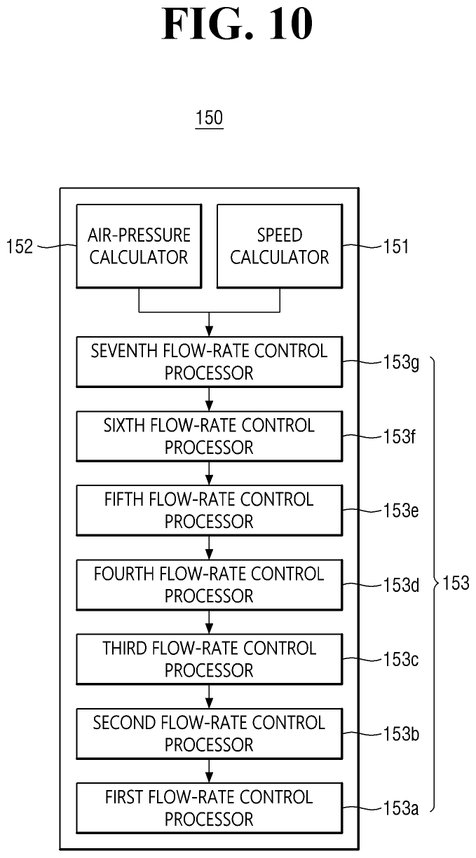

The control processing device 150 will be described in further detail later with reference to FIG. 10 and the like.

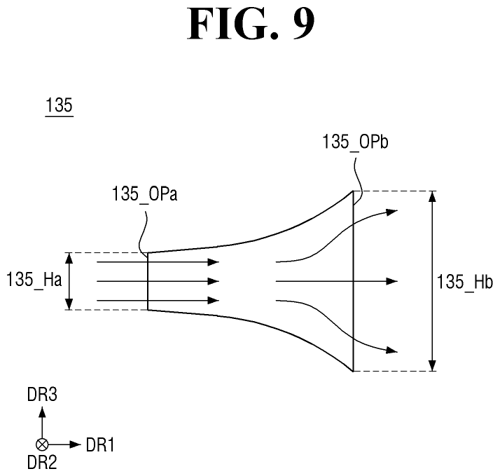

FIG. 8 is a perspective view of a flow-rate reducing member according to an embodiment of the present disclosure; and FIG. 9 is a side view of the flow-rate reducing member according to an embodiment.

Referring to FIGS. 8 and 9, the flow-rate reducing member 135 may have a shape extended in the second direction DR2. The flow-rate reducing member 135 may include a front opening 135_OPa and a rear opening 135_OPb.

In some embodiments, the flow-rate reducing member 135 may have a shape that becomes wider from the front to the rear. For example, referring to FIG. 9, the flow-rate reducing member 135 may have a shape of a fallopian tube on a side or cross-section. A height 135_Ha of the front opening 135_OPa in the third direction DR3 may be smaller than a height 135_Hb of the rear opening 135_OPb in the third direction DR3. As the flow-rate reducing member 135 has a shape that becomes wider from the front side to the rear side, a flow rate of air may be reduced toward the rear side according to Bernoulli's principle. In this manner, it is possible to prevent or substantially prevent particles from penetrating into another cassette transport device 10 that follows.

FIG. 10 is a block diagram of a control processing device according to an embodiment of the present disclosure; and FIG. 11 is a diagram conceptually illustrating a process of adjusting a flow rate by a control processing device and a flow-rate adjusting unit according to an embodiment of the present disclosure.

Referring to FIGS. 10 and 11, the control processing device 150 may control a strength of the flow maintaining members 131. The control processing device 150 may include a speed calculator 151, an air-pressure calculator 152, and a plurality of flow-rate control processors 153.

The speed calculator 151 may receive speed information SPD from the speed sensing unit 141. The speed calculator 151 may calculate a strength (e.g., a required strength) of the flow-rate maintaining members 131 based on the speed information SPD provided from the speed sensing unit 141. For example, the speed calculator 151 may analyze a correlation between the speed of the main body 110 and the flow rate of air to calculate the required strength of the flow-rate maintaining members 131.

The air-pressure calculator 152 may receive air-pressure information APD from the air-pressure sensing units 142. The air-pressure calculator 152 may calculate the required strength of the flow-rate maintaining members 131 based on the air-pressure information APD provided from the air-pressure sensing unit 142. For example, the air-pressure calculator 152 may analyze a correlation between air pressure and flow rate of air to calculate the required strength of the flow-rate maintaining members 131. As another example, the air-pressure calculator 152 may analyze the air-pressure information APD on the flow rate of air received directly from the air-pressure sensing units 142 to calculate the required strength of the flow-rate maintaining members 131.

Although the speed calculator 151 and the air-pressure calculator 152 are independent individual elements in the example shown in the drawings, embodiments of the present disclosure are not limited thereto, and the speed calculator 151 and the air-pressure calculator 152 may be implemented as a single calculator and may calculate the speed, air-pressure, and/or flow rate of air of the main body 110.

In some embodiments, when the flow-rate maintaining members 131 include fans, the speed calculator 151 and the air-pressure calculator 152 may calculate the required wind strength of the fans. Depending on the required wind strength, the strength of the flow-rate maintaining members 131, i.e., the fans, may be determined.

The plurality of flow-rate control processors 153 may control the strength of the flow-rate maintaining members 131 based on the calculated information (CCD) received from the speed calculator 151 and the air-pressure calculator 152. The calculated information CCD may contain information of the strength of the flow-rate maintaining members 131 required according to the speed, air pressure, and/or flow rate of the main body 110. For example, the flow-rate control processor 153 may receive the calculated information CCD from the speed calculator 151 and the air-pressure calculator 152. The flow-rate control processor 153 may generate a flow-rate control member control signal FCS for controlling the strength of the flow-rate control members 131 based on the provided calculated information CCD. The flow-rate maintaining members 131 may change their strength by receiving the flow-rate maintaining member control signal FCS.

The flow-rate control processors 153 may control the strengths of the plurality of flow-rate maintaining members 131, respectively. For example, the flow-rate control processors 153 may include first to seventh flow-rate control processors 153a, 153b, 153c, 153d, 153e, 153f, and 153g. According to an embodiment, a number of the flow-rate control processors 153 may be equal to a number of the flow-rate maintaining members 131, but embodiments of the present disclosure are not limited thereto. The first to seventh flow-rate control processors 153a, 153b, 153c, 153d, 153e, 153f, and 153g may be connected to the first to seventh flow-rate maintaining members 131a, 131b, 131c, 131d, 131e, 131f, and 131g, respectively, and may provide first to seventh flow-rate maintaining member control signals FCSa, FCSb, FCSc, FCSd, FCSe, FCSf, and FCSg to the first to seventh flow-rate maintaining members 131a, 131b, 131c, 131d, 131e, 131f, and 131g, respectively. As the first to seventh flow-rate maintaining members 131a, 131b, 131c, 131d, 131e, 131f, and 131g receive different first to seventh flow-rate maintaining member control signals FCSa, FCSb, FCSc, FCSd, FCSe, FCSf, and FCSg, the first to seventh flow-rate maintaining members 131a, 131b, 131c, 131d, 131e, 131f, and 131g may be driven with different strengths.

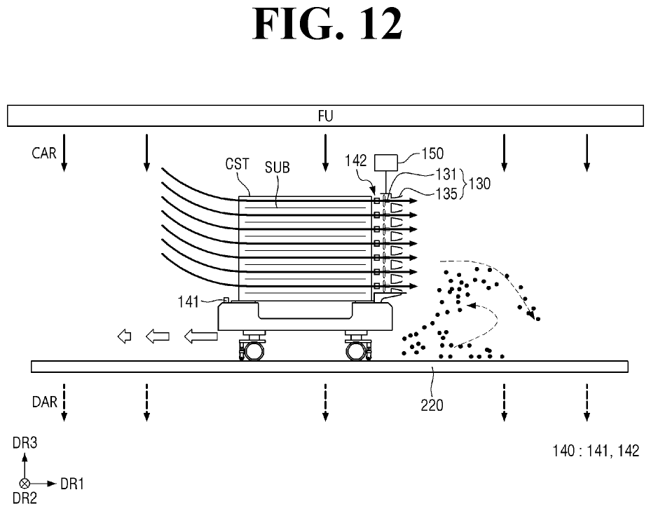

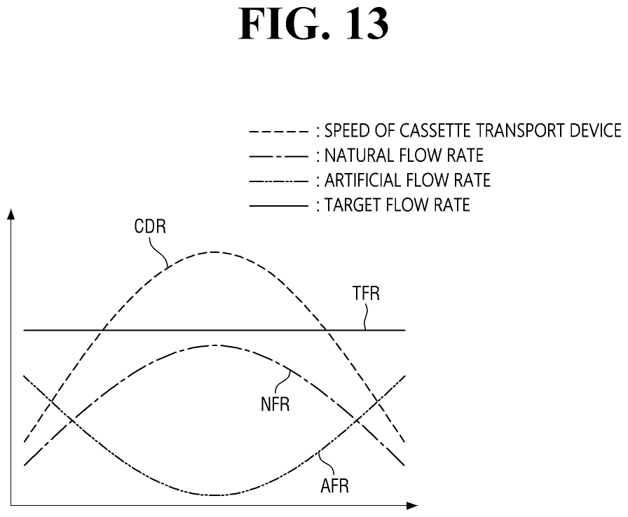

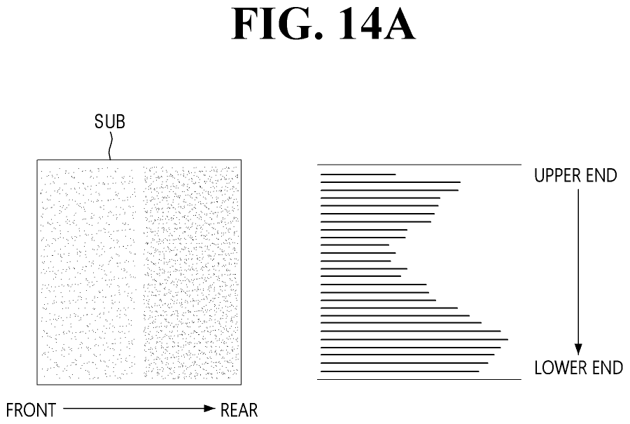

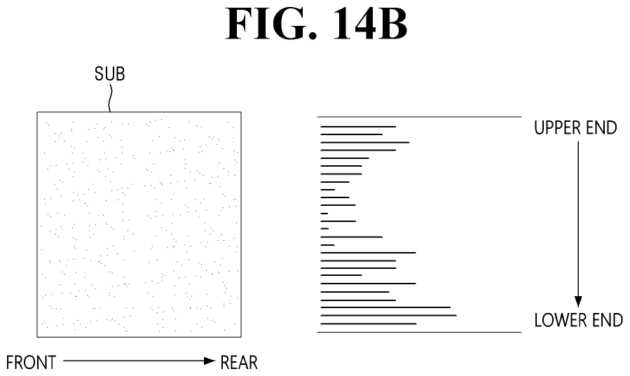

FIG. 12 is a side view showing a cassette transport device according to an embodiment when it is decelerating. FIG. 13 is a graph showing the flow rate according to the speed of the cassette transport device according to an embodiment. FIGS. 14A and 14B are graphs for comparing a degree of contamination of substrates transported by the cassette transport device according to an embodiment with a degree of contamination of substrates transported by a comparative cassette transport device.

Referring to FIGS. 12 and 13, particles on the travel rail 220 may be scattered into the air by a vortex behind the cassette transport device 10 that is generated when the cassette transport device 10 decelerates.

As shown in the graph of FIG. 13, when the cassette transport device 10 decelerates, the flow of air passing through the cassette CST may be weakened. For example, in the graph of FIG. 13, when a speed CDR of the cassette transport device 10 increases, a natural flow rate NFR of air also increases proportionally. When the speed CDR of the cassette transport device 10 decreases, the natural flow rate NFR of air may also decrease proportionally.

When the speed CDR of the cassette transport device 10 decreases, the natural flow rate NFR of the air passing through the cassette CST decreases, and, thus, the particles scattered into the air by the vortex behind the cassette transport device 10 may be introduced into the cassette CST.

According to the cassette transport device 10 according to an embodiment, when the speed of the cassette transport device 10 decreases, the strength of the flow-rate maintaining members 131 is increased such that the flow rate can be maintained. When the speed of the cassette transport device 10 increases, the strength of the flow-rate maintaining members 131 is decreased such that the flow rate can be maintained. For example, when the natural flow rate NFR decreases, an artificial flow rate AFR may be increased through the flow-rate maintaining members 131, and, when the natural flow rate NFR increases, the artificial flow rate AFR may be decreased. Accordingly, a target flow rate TFR can be maintained constant. In this manner, it is possible to prevent or substantially prevent particles scattered into the air by the vortex behind the cassette transport device 10 from being introduced into the cassette CST.

In addition, according to the cassette transport device 10 according to an embodiment, even if the speed CDR of the cassette transport device 10 changes, the target flow rate TFR is maintained constant, such that the clean air CAR purified by the air filter unit FU can be continuously and constantly introduced into the cassette CST from the front of the cassette transport device 10. In this manner, the clean air CAR can be continuously supplied to the substrates SUB loaded in the cassette CST to prevent or substantially prevent particles from being settled on the substrates SUB.

Incidentally, while the cassette transport device 10 is moving, a layer (e.g., FLa, FLb, FLc, FLd, FLe, FLf, and FLg) of the cassette CST at a higher level may be affected more by the air filter unit FU than a layer of the cassette CST at a lower level. A layer of the cassette CST at a lower level may be more affected by the flow of air moving toward the cassette CST from the front along the main body 110 than a layer of the cassette CST at a higher level.

According to the cassette transport device 10 according to an embodiment, the flow-rate maintaining members 131 disposed for the respective layers of the cassette CST may be individually controlled according to the air pressure and/or flow rate of air of the respective layers of the cassette CST. Therefore, it is possible to maintain a uniform or substantially uniform air flow for each of the layers in the cassette CST.

Referring to FIGS. 14A and 14B, the degree of contamination of the substrate SUB transported by a comparative cassette transport device is compared with that of the cassette transport device 10 according to an embodiment of the present disclosure. FIG. 14A shows the degree of contamination of the substrate SUB transported by the comparative cassette transport device, and FIG. 14B shows the degree of contamination of the substrate SUB transported by the cassette transport device 10 according to an embodiment of the present disclosure.

In both the substrate SUB transported by the comparative cassette transport device and the cassette transport device 10 according to an embodiment, a degree of contamination on the rear side may be greater than that of the front side. As described above, this may be due to particles scattered by a vortex generated behind the cassette transport device 10 when the cassette transport device 10 decelerates.

In addition, in both the substrate SUB transported by the comparative cassette transport device and the cassette transport device 10 according to an embodiment, the degree of contamination on the top and bottom layers may be greater than that of the intermediate layers. This may be because the particles scattered by the vortex are likely to settle on the bottom layer which is close to the travel rail 220. In addition, the particles from the ceiling by gravity are likely to settle on the top layer.

According to the cassette transport device 10 according to an embodiment, the degree of contamination of the substrate SUB may be reduced compared to that of the comparative cassette transport device. This is because the strength of the flow-rate maintaining members 131 may be adjusted according to the speed CDR of the cassette transport device 10, and the strength of the layers of the flow-rate maintaining members 131 may be adjusted individually, such that continuous flow of air may be generated inside the cassette CST and behind the cassette CST to thereby prevent or substantially prevent the particles from settling on the substrates SUB, as described above.

Herein, a cassette transport device according to another embodiment of the present disclosure will be described. In the following description, the same or similar elements will be denoted by the same or similar reference numerals, and redundant descriptions may be omitted or briefly described.

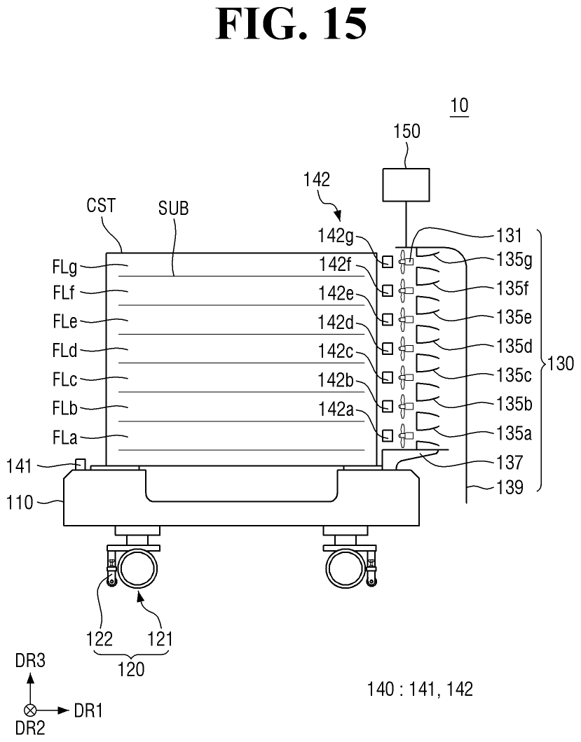

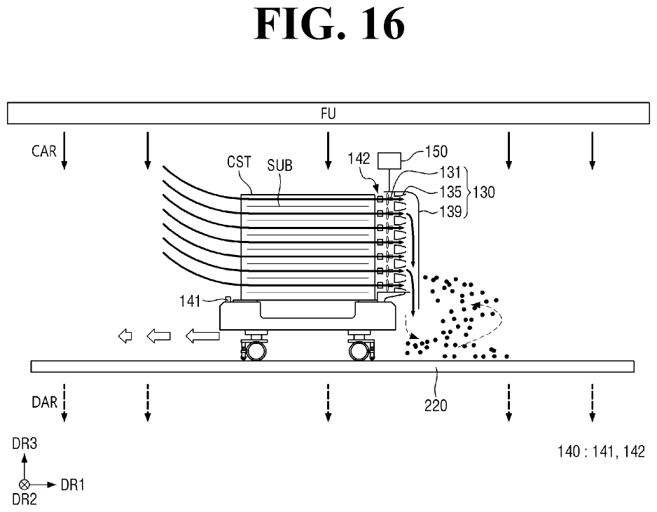

FIG. 15 is a side view of a cassette transport device according to another embodiment of the present disclosure; and FIG. 16 is a side view showing the cassette transport device according to the embodiment when it is decelerating.

The cassette transport device 10 according to the embodiment of FIGS. 15 and 16 is different from the cassette transport device 10 according to the embodiment described above with reference to FIG. 4 and the like in that a flow-rate adjusting unit 130 further includes a direction changing member 139.

More specifically, the flow-rate adjusting unit 130 of the cassette transport device 10 may further include the direction changing member 139.

The direction changing member 139 may include an opening toward the lower side, that is, a lower surface of the travel tunnel 210 or the travel rail 220. In an embodiment, the direction changing member 139 may have closed top and side surfaces and an open bottom. For example, the direction changing member 139 may be a duct with the closed top and side surfaces and the open bottom.

As such, the direction changing member 139 is disposed at a rear side of the flow-rate maintaining members 131 to change a direction of the air toward the lower side, such that it is possible to prevent or substantially prevent particles from penetrating another cassette transport device 10 that follows.

In some embodiments, the direction changing member 139 may be disposed to cover a part of the rear surface of the body 110. For example, the lower end of the direction changing member 139 may be positioned at a lower level than the upper surface of the main body 110.

In this manner, it is possible to more effectively prevent or substantially prevent particles scattered by the vortex behind the cassette transport device 10 from entering the inside of the cassette CST on the rear side of the cassette transport device 10.

While some embodiments have been described herein, those skilled in the art will appreciate that many variations and modifications can be made to the embodiments without substantially departing from the principles of the invention. Therefore, the disclosed embodiments of the invention are used in a generic and descriptive sense and not for purposes of limitation.

What is claimed is:

1. A cassette transport device comprising:
a main body;
a travel unit to move the main body; and
a plurality of flow-rate maintaining members to generate a flow of air in a direction opposite to a traveling direction of the main body,
wherein flow-rate maintaining members of the plurality of flow-rate maintaining members are stacked on one another on the main body, arranged on a rearward side with respect to the traveling direction of the main body, and comprise a plurality of fans.

2. The cassette transport device of claim 1, further comprising:
a speed sensing unit to measure a speed of the main body;
a plurality of air-pressure sensing units arranged in front of the flow-rate maintaining members, respectively; and
a control processing device to control the plurality of flow-rate maintaining members,
wherein the control processing device is configured to generate a signal for controlling a strength of the flow-rate maintaining members based on information provided from the speed sensing unit and the air-pressure sensing units, and
wherein the air-pressure sensing units are located between the flow-rate maintaining members and an object to be moved, and are configured to measure air pressure and/or air flow rate in front of the plurality of flow-rate maintaining members.

3. The cassette transport device of claim 2, wherein the control processing device further comprises:
a speed calculator and an air-pressure calculator configured to calculate strengths of the flow-rate maintaining members based on the information provided from the speed sensing unit and the air-pressure sensing units, respectively; and
a plurality of flow-rate control processors configured to generate signals for controlling the strengths of the flow-rate maintaining members based on calculated information of the speed calculator and the air-pressure calculator.

4. The cassette transport device of claim 1, wherein the flow-rate maintaining members are respectively arranged at a side of a plurality of layers of an object to be moved.

5. The cassette transport device of claim 1, further comprising:
a plurality of flow-rate reducing members respectively arranged at a rear side of the flow-rate maintaining members,
wherein each of the flow-rate reducing members comprises a front opening and a rear opening, and
wherein the front opening is smaller than the rear opening.

6. The cassette transport device of claim 5, wherein the flow-rate reducing members have a shape that gradually widens from a front side to a rear side.

7. The cassette transport device of claim 1, further comprising:
a direction changing member arranged at a rear side of the flow-rate maintaining members,
wherein the direction changing member comprises an opening facing a lower side, and is arranged to cover a part of a rear surface of the main body.

8. The cassette transport device of claim 1,
wherein the travel unit comprises a main travel unit and an auxiliary travel unit arranged at a side of the main travel unit,
wherein the auxiliary travel unit comprises a vertical driver, and
wherein a lowest end of the auxiliary travel unit is configured to be selectively located at a lower level than a lowest end of the main travel unit by driving the vertical driver.

9. The cassette transport device of claim 1, wherein a strength of the flow-rate maintaining members is increased as a speed of the main body decreases.

10. A cassette transport device comprising:
a main body;
a travel unit to move the main body; and
a plurality of fans to generate a flow of air in a direction opposite to a traveling direction of the main body,
wherein fans of the plurality of fans are stacked on one another on the main body, and arranged on a rearward side with respect to the traveling direction of the main body.

11. The cassette transport device of claim 10, further comprising:
a speed sensing unit to measure a speed of the main body;
a plurality of air-pressure sensing units arranged in front of the plurality of fans, respectively; and
a control processing device to control the plurality of fans,
wherein the control processing device is configured to generate a signal for controlling wind strengths of the fans based on information provided from the speed sensing unit and the air-pressure sensing units.

12. The cassette transport device of claim 11, wherein the plurality of air-pressure sensing units is configured to measure air pressure and/or flow rate of air in front of the plurality of fans, respectively.

13. The cassette transport device of claim 11, wherein the plurality of air-pressure sensing units is arranged between the plurality of fans, respectively, and an object to be moved.

14. The cassette transport device of claim 11, wherein the control processing device comprises a speed calculator and an air-pressure calculator configured to respectively calculate wind strength of the fans based on information provided from the speed sensing unit and the air-pressure sensing units.

15. The cassette transport device of claim 14, wherein the control processing device further comprises a plurality of flow-rate controller processors to generate signals to control the wind strength of the fans, respectively, based on calculated information provided from the speed calculator and the air-pressure calculator.

16. A cassette transport system comprising:
the cassette transport device according to claim 1;
a travel tunnel to move the cassette transport device; and
an air filter unit arranged on the travel tunnel,
wherein an upper surface of the travel tunnel comprises a plurality of first openings, and
wherein the air filter unit is configured to inject clean air into the travel tunnel through the first openings.

17. The cassette transport system of claim 16,
wherein a lower surface of the travel tunnel comprises a plurality of second openings, and
wherein the air filter unit is configured to generate an airflow from the first openings toward the second openings.

18. The cassette transport system of claim 16, further comprising:
at least one stocker to store a cassette; and
a buffer unit located between the stocker and the cassette transport device to temporarily store and relay the cassette.

19. The cassette transport system of claim 18, wherein the stocker comprises a lifting device to lift the cassette, and at least one loading chamber to store the cassette.

20. The cassette transport system of claim 18, wherein the travel tunnel is configured to connect an upper portion of the stocker with an upper portion of another stocker.

21. A cassette transport system comprising:
the cassette transport device according to claim 10;
a travel tunnel to move the cassette transport device; and
an air filter unit arranged on the travel tunnel,
wherein an upper surface of the travel tunnel comprises a plurality of first openings, and
wherein the air filter unit is configured to inject clean air into the travel tunnel through the first openings.
